(19) United States
(12) Patent Application Publication
(10) Pub. No.: US 2025/0006503 A1
(43) Pub. Date: Jan. 2, 2025

(54) Semiconductor Structures and Methods of Forming Them

(71) Applicant: ChangXin Memory Technologies, Inc., Hefei City (CN)

(72) Inventors: Ting LIAN, Hefei City (CN); Yunfei FU, Hefei City (CN); Yuheng LIU, Hefei City (CN)

(21) Appl. No.: 18/547,497

(22) PCT Filed: Aug. 1, 2022
(86) PCT No.: PCT/CN2022/109551

§ 371 Date: Aug. 22, 2023

(30) Foreign Application Priority Data
Jul. 20, 2022 (CN) 202210859721.2

(51) Int. Cl. H01L 21/308

(52) U.S. Cl. CPC H01L 21/3086; H01L 21/308; H01L 21/3085

(57) ABSTRACT

The disclosure relates to a semiconductor structure and a method for forming it. The method includes: providing a substrate; forming an initial carbon film layer on the surface of the substrate, the initial carbon film layer includes at least SP² hybrid bonds; implanting modifying ions into the initial carbon film layer to convert the SP² hybrid bonds into SP³ hybrid bonds to obtain the target carbon film layer. Applying the method can increase the hardness of the carbon film layer. In addition the etching selectivity ratio increases during the etch process using the carbon film as a hard mask, because the carbon film layer is not easily deformed in etch, which can ensure the patterned shape with improved etch window so to increase the product yield. Meanwhile, higher carbon hardness of the film layer can properly reduce the carbon film thickness during etch, saving carbon materials and reducing manufacturing costs.

### CROSS REFERENCES TO RELATED APPLICATIONS

This disclosure claims the priority of the Chinese patent application with application number 202210859721.2, entitled “Semiconductor Structures and Methods of Forming Them”, filed on Jul. 20, 2022, the content of which is incorporated herein by reference in its entirety.

### TECHNICAL FIELD

The present disclosure relates to the field of semiconductor technology, in particular, to semiconductor structures and methods for forming the same.

### BACKGROUND

The patterning process is one of the important processes in the semiconductor device manufacturing process. At present time, a carbon film layer is often used as a hard mask in the patterning process; however, the hardness of the existing carbon film layer is low. Deformation from damage in etch process leads to deformation of the etching window, resulting in low product yield.

It should be noted that the information disclosed in the above background section is only for enhancing the understanding of the background of the present disclosure, and therefore may include information that is not known to those of ordinary skill in the art.

### SUMMARY

In view of this, the present disclosure provides a semiconductor structure and a forming method thereof, which can increase the hardness of the carbon film layer and improve product yield.

According to one aspect of the present disclosure, a method for forming a semiconductor structure is provided, including:

providing a substrate;

forming an initial carbon film layer on the surface of the substrate, the initial carbon film layer includes at least SP² hybrid bonds; and

implanting modifying ions into the initial carbon film layer to convert the SP² hybrid bonds into SP³ hybrid bonds to obtain the target carbon film layer.

In an exemplary embodiment of the present disclosure, the hardness of the target carbon film layer is greater than the hardness of the initial carbon film layer.

In an exemplary embodiment of the present disclosure, the etching selectivity ratio of the target carbon film layer is higher than the etching selectivity ratio of the initial carbon film layer.

In an exemplary embodiment of the present disclosure, the method forming an initial carbon film layer is formed on the surface of the substrate, wherein the initial carbon film layer has at least SP² hybrid bonds, the method includes:

plasma-bombarding the carbon-containing gas at a first preset temperature, a first preset power, a first preset frequency, and a first preset pressure to form an initial carbon film attached to the surface of the substrate.

In an exemplary embodiment of the present disclosure, the carbon-containing gas includes cyclopropane.

In an exemplary embodiment of the present disclosure, the first preset temperature includes a range of 300° C.˜650° C., the first preset power includes a range of 1500 W˜2500 W, and the first preset frequency includes a range of 10 MHZ˜15 MHZ, the first preset pressure includes a range of 3 torr˜10 torr.

In an exemplary embodiment of the present disclosure, modifying ions are implanted into the initial carbon film layer, so that the SP² hybrid bonds are converted into SP³ hybrid bonds to obtain a target carbon film layer, the process includes:

ionizing the modifying gas at a second preset temperature to form modifying ions;

accelerating the modifying ions to form a high-energy ion beam; and

injecting a high-energy ion beam into the initial carbon film layer after the ion beam passes through a high-speed electric field to form a target carbon film layer.

In an exemplary embodiment of the present disclosure, the modifying gas includes carbon monoxide, and the modifying ions include carbon ions.

In an exemplary embodiment of the present disclosure, the modifying gas includes diborane, and the modifying ions include boron ions.

In an exemplary embodiment of the present disclosure, the second preset temperature is in a normal temperature range (room temperature to.

In an exemplary embodiment of the present disclosure, the thickness of the initial carbon film layer includes a range of 100 nm to 300 nm.

In an exemplary embodiment of the present disclosure, the implantation depth of the modifying ions of the initial carbon film layer is less than ⅔ of the thickness of the initial carbon film layer.

In an exemplary embodiment of the present disclosure, the implantation amount of the modifying ions is 1×10¹⁵ ions/cm²˜4×10¹⁵ Ions/cm².

According to one aspect of the present disclosure, there is provided a semiconductor structure comprising:

a substrate;

a target carbon film layer, the target carbon film layer comprising SP² hybrid bonds and SP³ hybrid bonds, the target carbon film layer is obtained by implanting modifying ions to the initial carbon film layer formed on the substrate. The SP² hybrid bond content of the target carbon film layer is higher than the SP² hybrid bond content of the initial carbon film layer.

In an exemplary embodiment of the present disclosure, the hardness of the target carbon film layer is greater than the hardness of the initial carbon film layer.

In an exemplary embodiment of the present disclosure, the etching selectivity ratio of the target carbon film layer is higher than the etching selectivity ratio of the initial carbon film layer.

In the disclosed semiconductor structure and its formation method, the orbit of the SP² hybridization bond in the initial carbon film layer is an equilateral triangle structure similar to graphene, and the carbon atom forms a covalent single bond with three adjacent carbon atoms through the SP² hybridization orbital, at this time, there is still a lone pair of electrons in the carbon atom structure that does not participate in hybridization, resulting in a more active SP² hybrid bond and a lower hardness of the carbon film; when the modifying ions enter the initial carbon film, the lone pair of electrons obtaining the energy transition causes the formation of SP³ hybrid bonds between adjacent carbon atoms. The orbit of the SP³ hybrid bonds is a diamond-like regular tetrahedral structure. The valence bond constitutes a regular tetrahedral structure, and all C atom valence electrons participate in the formation of covalent bonds. At this time, there are no free electrons, so the SP³ hybrid bond is relatively hard. Therefore, the hardness of the carbon film layer after implanting modifying ions is relatively large, and the etching selectivity ratio increases in the etching process, and the carbon film layer is not easily deformed, which can ensure the etching shape of the etching window and improve the product yield; at the same time, due to the improved hardness of the carbon film layer, and the thickness of the carbon film layer can be appropriately reduced during the etching process, which can save carbon materials and reduce manufacturing costs.

It is to be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of this specification, illustrate embodiments consistent with the disclosure and together with the description serve to explain the principles of the disclosure. Apparently, the drawings in the following description are only some embodiments of the present disclosure, and those skilled in the art can obtain other drawings according to these drawings without creative efforts.

FIG. 1 is a schematic diagram of an etching window in the related art;

FIG. 2 is a flowchart of an etching method for a semiconductor structure in an embodiment of the present disclosure;

FIG. 3 is a schematic diagram of an initial carbon film layer in an embodiment of the present disclosure;

FIG. 4 is a schematic diagram of a target carbon film layer in an embodiment of the present disclosure;

FIG. 5 is a schematic diagram of the XPS energy spectrum of the initial carbon film layer in the embodiment of the present disclosure;

FIG. 6 is a schematic diagram of the XPS energy spectrum of the target carbon film layer in the embodiment of the present disclosure;

FIG. 7 is a schematic diagram of an etched window in an embodiment of the present disclosure.

### EXPLANATION OF REFERENCE SIGNS

100, film layer to be etched; 101, etching window; 200, carbon film layer; 1, substrate; 2, initial carbon film layer; 3, target carbon film layer; 4, substrate; 5, film layer to be measured; 501, Etched window; 300, SP² hybrid bond; 400, SP³ hybrid bond.

### DETAILED DESCRIPTION OF THE PREFERRED EMBODIMENTS

Example embodiments will now be described more fully with reference to the accompanying drawings. Example embodiments may, however, be embodied in many forms and should not be construed as limited to the embodiments set forth herein; rather, these embodiments are provided so that this disclosure will be thorough and complete, and will fully convey the concept of example embodiments to those skilled in the art. The same reference numerals in the drawings denote the same or similar structures, and thus their detailed descriptions will be omitted. Furthermore, the drawings are merely schematic illustrations of the present disclosure and are not necessarily drawn to scale.

Although relative terms such as “upper” and “lower” are used in this specification to describe the relative relationship of one component of an icon to another component, these terms are used in this specification only for convenience, for example, according to the description in the accompanying drawings directions for the example described above. It will be appreciated that if the illustrated device is turned over so that it is upside down, then elements described as being “upper” will become elements that are “lower”. When a structure is “on” another structure, it may mean that a structure is integrally formed on another structure, or that a structure is “directly” placed on another structure, or that a structure is “indirectly” placed on another structure through another structure, other structures.

The terms “a”, “an”, “the”, “said” and “at least one” are used to indicate the presence of one or more elements/components/etc; the terms “comprising” and “have” are used to indicate an open inclusion which means that there may be additional elements/components/etc. in addition to the listed elements/components/etc; the terms “first” and “second” etc. A limit on the number of its objects.

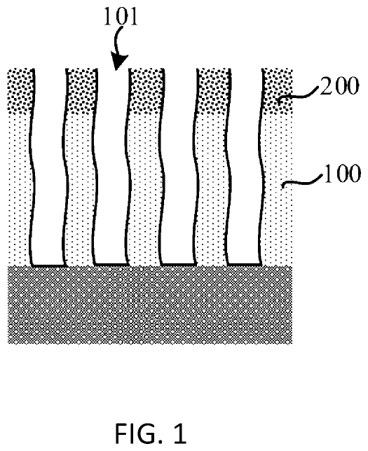

During the manufacturing process of a semiconductor device, an etching process is usually used for patterning to form a desired pattern. During the patterning process, a mask layer needs to be formed on the surface of the film layer 100 to be etched, and the mask layer is subjected to photolithography process to form a mask pattern, and then the mask pattern is transferred to the film layer 100 to be etched by etching. The carbon film layer 200 is one of the commonly used mask layers. At present, in the process of etching with the carbon film layer 200 as the mask layer, since the hardness of the carbon film layer 200 is small, the loss in the etching process is relatively large, so it is necessary to coat a carbon film layer 200 with a larger thickness, and the manufacturing cost is higher; and in the etching process, the etching selection of the carbon film layer 200 is relatively small, and the loss of the mask material at the edge of the mask pattern is relatively large, resulting in the mask pattern being deformed, which in turn leads to deformation of the etching window 101 finally formed in the film layer 100 to be etched (as shown in FIG. 1), and the product yield is low.

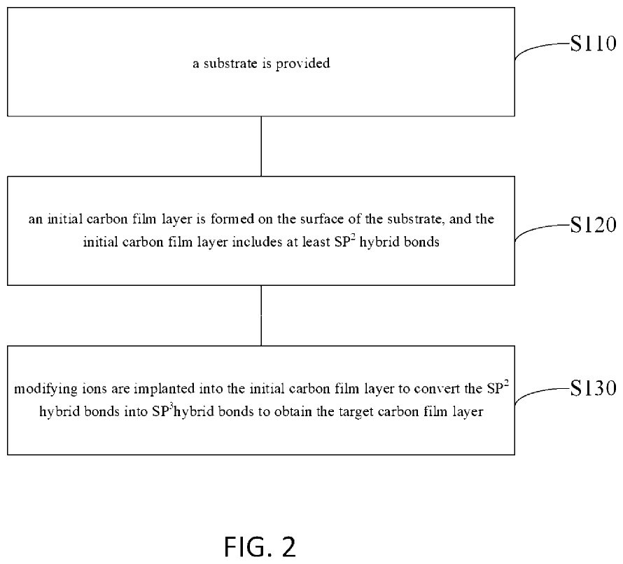

Based on this, an embodiment of the present disclosure provides a method for forming a semiconductor structure. FIG. 2 shows a flow chart of the method for forming a semiconductor structure of the present disclosure. Referring to FIG. 2, the method of forming the present disclosure includes step S110-step S130, where:

Step S110, providing a substrate;

Step S120, forming an initial carbon film layer on the surface of the substrate, the initial carbon film layer at least including SP² hybrid bonds;

Step S130, implanting modifying ions into the initial carbon film layer, so as to convert the SP² hybrid bonds into SP³ hybrid bonds to obtain the target carbon film layer.

In the formation method of the semiconductor structure disclosed in the present disclosure, the orbit of the SP² hybrid bond in the initial carbon film layer is an equilateral triangle structure similar to graphene, and the carbon atom forms a covalent single bond with three adjacent carbon atoms through the SP² hybrid orbit, At this time, there is still a lone pair of electrons in the carbon atomic structure that does not participate in hybridization, resulting in a more active SP² hybrid bond and a lower hardness of the carbon film; when the modifying ions enter the initial carbon film, the lone pair of electrons gains energy A transition occurs to form a SP³ hybrid bond between adjacent carbon atoms. The orbit of the SP³ hybrid bond is a diamond-like regular tetrahedral structure, and each carbon atom forms a covalent bond with the other four carbon atoms in an SP³hybrid orbit, bond, forming a regular tetrahedral structure, and all C atom valence electrons participate in the formation of covalent bonds. At this time, there are no free electrons, so the SP³ hybrid bond is relatively hard. Therefore, the hardness of the carbon film layer after implanting modifying ions is relatively large, and the etching selectivity ratio increases in the etching process, and the carbon film layer is not easily deformed, which can ensure the etching shape of the etching window and improve the product yield; at the same time, due to the increased hardness of the carbon film layer, and the thickness of the carbon film layer can be appropriately reduced during the etching process, which can save carbon materials and reduce manufacturing costs.

The technical details in the steps of the method for forming the semiconductor structure of the present disclosure are described in detail below:

As shown in FIG. 2, in step S110, a substrate is provided.

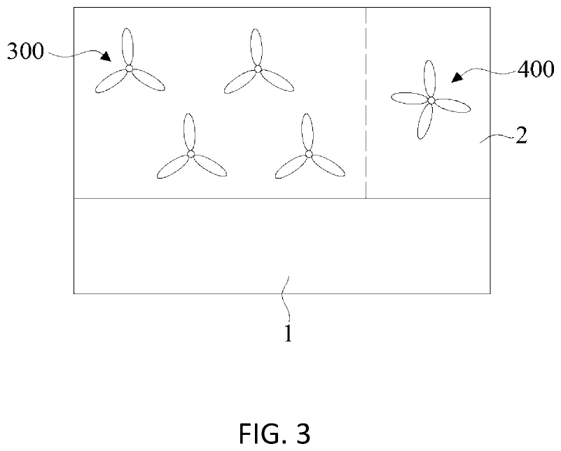

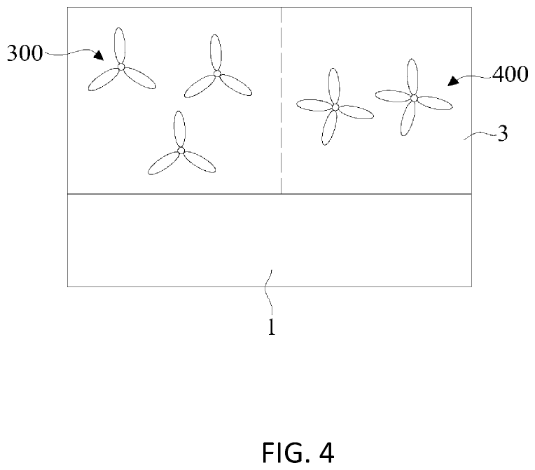

As shown in FIGS. 3 and 4, the substrate I can be in a flat plate structure, which can be rectangular, circular, elliptical, polygonal or irregular, and its material can be silicon or other semiconductor materials. The shape and material are specially limited.

As shown in FIG. 2, in step S120, an initial carbon film layer is formed on the surface of the substrate 1, and the initial carbon film layer includes at least SP² hybrid bonds.

As shown in FIG. 3, the initial carbon film layer 2 can be a thin film formed on the substrate 1 or a coating formed on the substrate 1, and the type of the initial carbon film layer 2 is not specifically limited here. For example, the initial carbon film layer 2 can be formed on the surface of the substrate 1 by means of chemical vapor deposition, physical vapor deposition, atomic layer deposition, vacuum evaporation or magnetron sputtering. The material of initial carbon film layer 2 can be carbon, and its interior can comprise SP² hybridization bond 300, certainly, initial carbon film layer 2 can also comprise SP³ hybridization bond 400, the hybridization bond in this initial carbon film layer 2 The type is specially limited.

In some embodiments of the present disclosure, the thickness of the initial carbon film layer 2 can be in a range of 100 nm˜300 nm, for example, it can be 100 nm, 150 nm, 200 nm, 250 nm or 300 nm, of course, the thickness of the initial carbon film layer 2 can also be others, they won't be list one by one here.

In an exemplary embodiment of the present disclosure, plasma can be performed on the carbon-containing gas by using an inert gas at a first preset temperature, a first preset power, a first preset frequency, and a first preset pressure. The bombardment generates a large amount of active plasma, which can be deposited on the surface of the substrate 1 to form an initial carbon film layer 2 attached to the surface of the substrate 1

In some embodiments of the present disclosure, the first preset temperature may be a higher temperature. For example, the first preset temperature may include 300° C, to 650° C., for example, it may be 300° C., 400° C., 500° C.° C., 600° C, or 650° C., of course, the first preset temperature can also be other temperature values, which will not be listed here.

In some embodiments of the present disclosure, the first preset power may be higher power, for example, the first preset power may include 1500 W˜2500 W, for example, it may be 1500 W, 1800 W, 2100 W, 2400 W or 2500 W, of course, the first preset power may also be other amount of power, which will not be listed here.

In some embodiments of the present disclosure, the first preset frequency can be a higher frequency, for example, the first preset frequency can include 10 MHZ˜15 MHZ, for example, it can be 10 MHZ, 11 MHZ, 12 MHZ, 13 MHZ, 13.56 MHZ, 14 MHZ or 15 MHZ, of course, the first preset frequency can also be other frequency values, which will not be listed here.

In some embodiments of the present disclosure, the first preset pressure may include higher pressure, for example, the first preset pressure may include 3 torr˜10 torr, for example, it may be 3 torr, 5 torr, 7 torr, 9 torr or 10 torr, of course, the first preset pressure may also be other pressure values, which will not be listed here.

In an exemplary embodiment of the present disclosure, the carbon-containing gas may include cyclopropane (C₃H₆), and cyclopropane (C₃H₆) may provide carbon atoms for forming the initial carbon film layer 2. Of course, the carbon-containing gas can also be other gases, for example, it can also be ethylene (C₂H₄), etc., and there is no special limitation on the carbon-containing gas here.

In an exemplary embodiment of the present disclosure, chemical vapor deposition may be used, using cyclopropane (C₃H₆) as a carbon-containing gas, at a high temperature of 550° C., a power of 2100 W, a high frequency of 13.56 Mhz and an 8 torr pressure, the carbon-containing gas is bombarded with argon ions or helium ions under pressure, thereby generating a large amount of active carbon plasma, which can be deposited on the substrate 1 to form an initial carbon film 2.

In some embodiments of the present disclosure, a variety of different types of carbon film layers can be formed according to different formation conditions. The ratio of SP³ hybrid bond 400 to SP² hybrid bond 300 in each carbon film layer is different, and the SP³ hybrid bond can be screened out. The carbon film layer with a relatively high ratio of chemical bond 400 to SP² hybrid bond 300 is used as the initial carbon film layer 2 in the present disclosure.

For example, the first type of carbon film can be defined as an APFe film, and cyclopropane (C₃H₆) can be used as a carbon-containing gas to form an APFe film by atomic layer deposition at a temperature of 300° C, and a power of 1250 W., the proportion of SP² hybrid bond 300 in the APFe film layer is 83.81%, and the proportion of SP³ hybrid bond 400 is 16.19%; the second carbon film layer can be defined as the APF550 film layer, which can be cyclopropane (C₃H₆) is a carbon-containing gas. At a temperature of 550° C, and a power of 1600 W, the APF550 film is formed by the atomic layer deposition process. The proportion of the SP² hybrid bond 300 in the APF550 film is 75.63%, and the SP³hetero The proportion of chemical bond 400 is 24.37%; the third carbon film layer can be defined as a DLC film layer, and ethylene (C₂H₄) can be used as a carbon-containing gas at a temperature of 275° C, and a power of 400 W/2400 W. The DLC film layer is formed by the layer deposition process, and the proportion of SP² hybrid bond 300 in the DLC film layer is 71.16%, and the proportion of SP³hybrid bond 400 is 28.84%; the fourth carbon film layer can be defined as Kodiak The film layer can be cyclopropane (C₃H₆) as a carbon-containing gas, and the Kodiak film layer is formed by the atomic layer deposition process at a temperature of 630° C, and a power of 2100 W. After testing, the ratio of SP² hybrid bonds 300 in the Kodiak film layer is 70.14%, and the ratio of SP³ hybrid bond 400 is 29.76%. The Kodiak film layer can be used as the initial carbon film layer 2 in this disclosure.

As shown in FIG. 2, in step S130, modifying ions are implanted into the initial carbon film layer to convert the SP² hybrid bonds into SP³hybrid bonds to obtain the target carbon film layer.

The modifying ions can be implanted into the initial carbon film layer 2 by means of ion implantation, so as to obtain the target carbon film layer 3. After the modifying ion enters the initial carbon film layer 2, the carbon-hydrogen bond in the SP² hybrid bond 300 in the initial carbon film layer 2 breaks, and the carbon ion and the modifying ion recombine to form the SP³ hybrid bond 400, and the SP³ hybrid bond, each carbon atom in the chemical bond 400 forms a covalent bond with the other four carbon atoms through the SP³ hybrid orbital to form a regular tetrahedral structure, and all the valence electrons of the C atom participate in the formation of the covalent bond. At this time. there is no Free electrons, therefore, compared with the SP² hybrid bond 300, the SP³ hybrid bond 400 has a higher hardness, which makes the hardness of the final target carbon film layer 3 greater than that of the initial carbon film layer 2. Therefore, the hardness of the target carbon film layer 3 after implanting modifying ions is relatively large, and the etching selectivity ratio increases (that is, the etching selectivity ratio of the target carbon film layer 3 is higher than that of the initial carbon film layer 2 in the etching process), selection ratio), the target carbon film layer 3 is not easily deformed. which can ensure the etching shape of the etching window and improve product yield; at the same time, due to the increased hardness of the target carbon film layer 3, the target carbon film layer 3 can be appropriately reduced during the etching process. The thickness of the carbon film layer 3 can save carbon materials and reduce manufacturing costs.

In an exemplary embodiment of the present disclosure, the implantation depth of the modifying ions of the initial carbon film layer 2 is less than ⅔ of the thickness of the initial carbon film layer 2, on the one hand, it can avoid damaging its lower layer during ion implantation on the substrate 1, so to avoid the defects on the substrate 1 caused by ion implantation, which can improve the product yield; on the other hand, by controlling the implantation depth of the modifying ions, the structure of the upper part of the modifying ions and the initial carbon film layer 2 can be generated. reaction, and then make the final target carbon film layer 3 form the characteristics of high hardness on the top and low hardness on the bottom, and then make the target carbon film layer 3 in the process of etching as a hard mask subsequently, for the target carbon film layer 3, the etching rate on the side away from the substrate 1 is relatively small, and the etching rate on the side close to the substrate 1 is relatively large, so as to avoid that the target carbon film layer 3 being plasma-etched, and on one side, the etch rate is slowed down I the area close to the substrate I due to insufficient energy.

For example, the ion implantation depth of the initial carbon film layer 2 can be ⅕, ¼, ⅓ or ⅔ of the thickness of the initial carbon film layer 2, of course, it can also be other depths, which will not be repeated here. List them all.

In an exemplary embodiment of the present disclosure, the implantation amount of modifying ions is 1×10¹⁵ ions/cm²˜4×10¹⁵ ions/cm², for example, the implantation amount can be 1×10¹⁵ ions/cm², 2×10¹⁵ ions/cm², 3×10¹⁵ ions/cm² or 4×10¹⁵ ions/cm², of course, can also be other injection amounts, which will not be listed here.

In an exemplary embodiment of the present disclosure, modifying ions are implanted into the initial carbon film layer 2, so that the SP² hybrid bond 300 is converted into the SP³ hybrid bond 400, so as to obtain the target carbon film layer 3 (i.e. step S130) may include step S210-step S230, wherein:

Step S210, ionize the modifying gas at a second preset temperature to form modifying ions.

The modifying gas may be passed through the ion machine at a second preset temperature, and then the modifying gas is ionized to obtain modifying ions. In the embodiment of the present disclosure, the second preset temperature may be normal temperature (room temperature).

In some embodiments of the present disclosure, the modifying gas may be a carbon-containing gas, and the carbon-containing gas may be ionized by an ion machine to obtain carbon ions, that is, the modifying ions may be carbon ions. For example, the modifying gas may be carbon monoxide (CO). Of course, the modifying gas may also be other carbon-containing gases, which will not be listed here.

In other embodiments of the present disclosure, the modifying gas may be a boron-containing gas, and the boron-containing gas may be ionized by an ion machine to obtain boron ions, that is, the modifying ions may be boron ions. For example, the modifying gas may be diborane (B₂H₆). Of course, the modifying gas may also be other boron-containing gases, which will not be listed here.

It should be noted that the modifying ions can also be other ions, as long as the SP² hybrid bond 300 in the initial carbon film layer 2 can be converted into the SP³hybrid bond 400, there is no special limitation on the type of the modifying ion.

Step S220, accelerating the modifying ions to form a high-energy ion beam.

The electric field can be used to accelerate the modifying ions to obtain a high-energy high-energy ion beam.

Step S230, injecting the high-energy ion beam into the initial carbon film layer 2 after passing through a high-speed electric field, so as to form the target carbon film layer 3.

As shown in FIG. 4, the high-energy ion beam can be further accelerated by a high-speed electric field to increase the implantation energy of the high-energy ion beam, and the initial carbon film layer 2 after implanting modifying ions can be defined as the target carbon film layer 3.

When the modifying ion is a carbon ion, after the carbon ion enters the initial carbon film layer 2, the carbon-hydrogen bond in the initial carbon film layer 2 is broken, and the carbon atoms are recombined, and the original carbon-hydrogen bond is formed after recombination. The carbon-carbon bond increases the binding energy, which in turn helps to enhance the hardness of the carbon film layer, that is, the hardness of the target carbon film layer 3 is greater than the hardness of the initial carbon film layer 2. In the patterning process, the target carbon film layer can be Layer 3 is used as a mask layer, which can improve the etching selectivity ratio, and the target carbon film layer 3 is not easy to deform during the etching process, which can ensure the etching shape of the etching window and improve the product yield; meanwhile, in the process of forming the mask layer, it can properly reduce the thickness of the target carbon film layer 3, saving carbon materials and reducing manufacturing costs.

When the modifying ions are boron ions, after a boron ion enters the initial carbon film layer 2, the original carbon-hydrogen bond in the initial carbon film layer 2 is broken, and the recombination occurs between the carbon atom and the boron ion. After recombination, a carbon-carbon bond or a carbon-boron bond is formed, and the binding energy increases, which in turn helps to enhance the hardness of the carbon film layer.

In an exemplary embodiment of the present disclosure, by controlling the thickness of the initial carbon film layer 2 and the implantation conditions of modifying ions, the SP³hybrid bond 400 and the SP² hybrid bond in the final target carbon film layer 3 can be formed. The ratio of chemical bonds 300 is greater than 2:3. For example, the ratio of the SP³ hybrid bond 400 to the SP² hybrid bond 300 in the target carbon film layer 3 can be 2:3, 2.1:3, 2.2:3, 2.3:3 or 2.4:3, of course, the target carbon ratio of the SP³ hybrid bonds 400 to the SP² hybrid bonds 300 in the film layer 3 can also be other values, which are not listed here.

In an exemplary embodiment of the present disclosure, the ratio of SP² hybrid bonds 300 and SP³ hybrid bonds 400 in the target carbon film layer 3 can be detected after the implantation of modifying ions, so as to determine whether the target carbon film layer 3 is reached and whether the hardness of the initial carbon film layer 2 is improved.

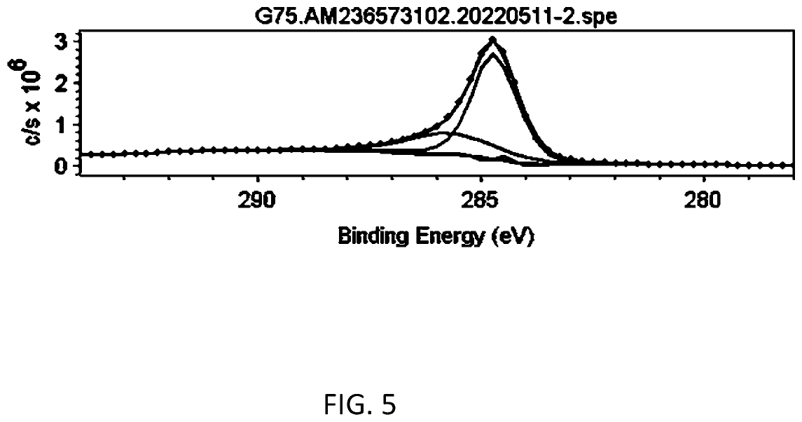

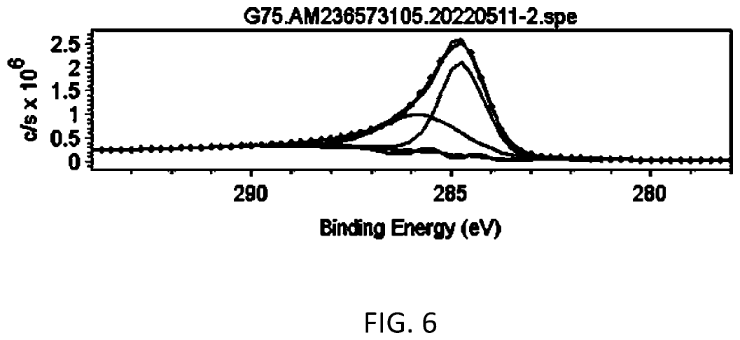

For example, the X-ray photoelectron spectrum (XPS) of the initial carbon film layer 2 and the target carbon film layer 3 can be collected respectively, and the SP² impurities in the target carbon film layer 3 can be judged according to the peak value in the XPS whether the ratio of SP² hybrid bond 300 to SP³ hybrid bond 400 is changed compared with the ratio of SP² hybrid bond 300 to SP³ hybrid bond 400 in the initial carbon film layer 2. FIG. 5 shows the XPS of the original carbon film layer 2 in the embodiment of the present disclosure, and FIG. 6 shows the XPS of the target carbon film layer 3 in the embodiment of the present disclosure, in the figure, the X-axis represents the binding energy; the Y-axis represents the photoelectron intensity; 284.7 ev is the characteristic peak of carbon SP² hybridization; the 285 ev binding energy represents the characteristic peak value of carbon SP³ hybridization; according to FIG. 5 and FIG. 6, it can be concluded that the peak area of SP³ hybridization in the target carbon film layer 3 becomes larger, indicating that the proportion of SP³ in the carbon film layer formed after the modifying ion implantation becomes larger.

After calculation, it can be known that the ratio of SP³ hybrid bond 400 and SP² hybrid bond 300 in the initial carbon film layer 2 is 29.76:70.24; the ratio of SP³hybrid bond 400 and SP² hybrid bond 300 in the target carbon film layer 3 is 42.15:57.85, compared with the initial carbon film layer 2, the proportion of SP³ hybrid bond 400 increased by 41.6%.

In order to further verify whether the hardness of the target carbon film layer 3 formed after the modifying ion implantation can be increased, and then determine whether the etching selectivity ratio of the target carbon film layer 3 formed after the modifying ion implantation can be increased. can be respectively adopted. The target carbon film layer 3 and the initial carbon film layer 2 are used as a mask layer, and the film layer to be tested is etched, and the target carbon film layer 3 is determined by comparing the morphology of the etching window formed in the film layer to be tested after etching if the etch selectivity ratio can be improved.

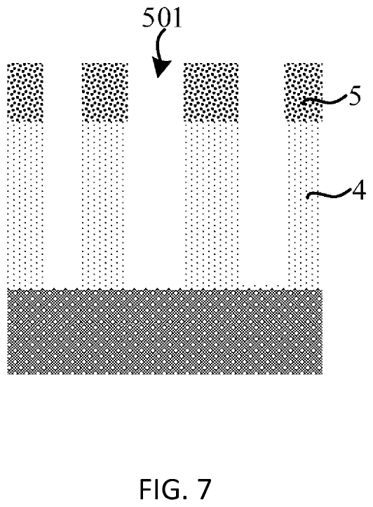

For example, as shown in FIG. 7, the film layer 5 to be tested can be formed on a substrate 4, the target carbon film layer 3 is formed on the surface of the film layer 5 to be tested, and at the same time, the film layer 5 to be measured is formed on another substrate 4. An initial carbon film layer 2 is formed on the surface of the film layer 5 to be tested; the same process is adopted to form the same mask pattern in the initial carbon film layer 2 and the target carbon film layer 3 respectively; the carbon film layer 2 and the target carbon film layer 3 are masks, and the same etching gas or etching solution is used to etch the film layer 5 to be tested to form an etching window 501; the initial carbon film layer 2 with the mask pattern and the microscopic appearance of the etching window 501 formed with the target carbon film layer 3 with the mask pattern as a mask, and then judge the etching selection of the target carbon film layer 3 by the microscopic appearance to see if the ratio is greater than the time selection ratio of the initial carbon film layer 2.

The side wall profile of the etching window 101 formed by using the initial carbon film layer 2 as a mask appears to have a large upper part and a narrower lower part; the side wall profile of the etching window 501 formed by using the target carbon film layer 3 as a mask is straighter and does not appear. The phenomenon that the large bottom is narrow indicates that the hardness of the target carbon film layer 3 is greater and the etching selectivity is higher.

In an exemplary embodiment of the present disclosure, since the hardness of the target carbon film layer 3 is increased compared with the initial carbon film layer 2, in the process of etching with the target carbon film layer 3 as a mask, the etching rate of the target carbon film layer 3 is lower than that of the initial carbon film layer 2, that is, the etching selectivity of the target carbon film layer 3 is higher than that of the initial carbon film layer 2.

In an exemplary embodiment of the present disclosure, after a large number of experimental verifications, the target carbon film layer obtained under the condition that the thickness of the initial carbon film layer 2 is 160 nm and the implantation amount of modifying ions is 3.00×10¹⁵ is finally obtained. The etching rate of the target carbon film layer 3 formed after modifying ion implantation was 32.9, which was 25% lower than that of the initial carbon film layer 2 (with an etching rate of 42.6) without modifying ion implantation.

It should be noted that although the various steps of the method for forming a semiconductor structure in the present disclosure are described in a specific order in the drawings, this does not require or imply that these steps must be performed in this specific order, or that all steps must be performed, follow the steps shown to achieve the desired result. Additionally or alternatively, certain steps may be omitted, multiple steps may be combined into one step for execution, and/or one step may be decomposed into multiple steps for execution, etc.

Embodiments of the present disclosure also provide a semiconductor structure, which can be formed by the method for forming a semiconductor structure in any of the above embodiments. As shown in FIG. 4, the semiconductor structure of the present disclosure can include a substrate 1 and a target carbon film layer 3 on 1, the target carbon film layer 3 can be obtained by implanting modifying ions to the initial carbon film layer 2 formed on the substrate 1, the content of the SP² hybrid bond of the target carbon film layer 3 It can be higher than the SP² hybrid bond content of the initial carbon film layer 2.

The SP³ hybrid bond 400 content in the semiconductor structure of the present disclosure is more, and the orbit of the SP³ hybrid bond 400 is a diamond-like regular tetrahedral structure, and each carbon atom forms a covalent bond with the other four carbon atoms through the SP³ hybrid orbit. bond, forming a regular tetrahedral structure, and all C atom valence electrons participate in the formation of covalent bonds. At this time, there are no free electrons, so the SP³ hybrid bond 400 is relatively hard. Therefore, the semiconductor structure of the present disclosure has relatively high hardness, and using it as a mask layer in the etching process can increase the etching selectivity ratio, and the semiconductor structure is not easily deformed during the etching process, which can ensure the etching shape of the etching window and improve product quality. At the same time, due to the high hardness of the semiconductor structure, the thickness of the semiconductor structure can be appropriately reduced during the etching process, which can save materials and reduce manufacturing costs.

As shown in FIGS. 3 and 4, the substrate I can be in a flat plate structure, which can be rectangular, circular, elliptical, polygonal or irregular, and its material can be silicon or other semiconductor materials. The shape and material are specially limited.

As shown in FIG. 4, the target carbon film layer 3 can be formed on the surface of the substrate 1, for example, an initial carbon film layer 2 can be formed on the substrate 1, and the initial carbon film layer 2 is implanted with modifying ions to form target carbon film layer 3.

In some embodiments of the present disclosure, the thickness of the initial carbon film layer 2 can be in a range of 100 nm˜300 nm, for example, it can be 100 nm, 150 nm, 200 nm, 250 nm or 300 nm, of course, the thickness of the initial carbon film layer 2 can also be others, they won't be listed one by one here.

The modifying ions can be implanted into the initial carbon film layer 2 by means of ion implantation, so as to obtain the target carbon film layer 3. After the modifying ion enters the initial carbon film layer 2, the carbon-hydrogen bond in the SP² hybrid bond 300 in the initial carbon film layer 2 breaks, and the carbon ion and the modifying ion recombine to form the SP³hybrid bond 400, and the SP³ hybrid bond, each carbon atom in the chemical bond 400 forms a covalent bond with the other four carbon atoms through the SP³ hybrid orbital to form a regular tetrahedral structure, and all the valence electrons of the C atom participate in the formation of the covalent bond. At this time, there is no Free electrons, therefore, compared with the SP² hybrid bond 300, the SP³ hybrid bond 400 has a higher hardness, which makes the hardness of the final target carbon film layer 3 greater than that of the initial carbon film layer 2. Therefore, the hardness of the target carbon film layer 3 after implanting modifying ions is relatively large, and the etching selectivity ratio increases (that is, the etching selectivity ratio of the target carbon film layer 3 is higher than that of the initial carbon film layer 2 in the etching process), selection ratio), the target carbon film layer 3 is not easily deformed, which can ensure the etching shape of the etching window and improve product yield; at the same time, due to the increased hardness of the target carbon film layer 3, the target carbon film layer 3 can be appropriately reduced during the etching process. The thickness of the carbon film layer 3 can save carbon materials and reduce manufacturing costs.

In some embodiments of the present disclosure, the modifying ions can be carbon ions. After the carbon ions enter the initial carbon film layer 2, the carbon-hydrogen bond in the initial carbon film layer 2 is broken, and recombination occurs between carbon atoms. After the carbon-hydrogen bond recombination, a carbon-carbon bond is formed, and the binding energy increases, which in turn helps to enhance the hardness of the carbon film layer, that is, the hardness of the target carbon film layer 3 is greater than the hardness of the initial carbon film layer 2. In the process, the target carbon film layer 3 can be used as a mask layer, which can improve the etching selectivity ratio, and the target carbon film layer 3 is not easily deformed during the etching process, which can ensure the etching shape of the etching window and improve the product yield; During the masking process, the thickness of the target carbon film layer 3 can be appropriately reduced, saving carbon materials and reducing manufacturing costs.

In some embodiments of the present disclosure, the modifying ions can be boron ions. After the boron ions enter the initial carbon film layer 2, the carbon-hydrogen bond in the initial carbon film layer 2 is broken, and recombination occurs between carbon atoms and boron ions . . , the original carbon-hydrogen bonds are recombined to form carbon-carbon bonds or carbon-boron bonds, and the binding energy increases, which in turn helps to enhance the hardness of the carbon film layer.

In an exemplary embodiment of the present disclosure, by controlling the thickness of the initial carbon film layer 2 and the implantation conditions of modifying ions, the SP³ hybrid bond 400 and the SP² hybrid bond in the final target carbon film layer 3 can be formed. The ratio of chemical bonds 300 is greater than 2:3. For example, the ratio of the SP³ hybrid bond 400 to the SP² hybrid bond 300 in the target carbon film layer 3 can be 2:3, 2.1:3, 2.2:3, 2.3:3 or 2.4:3, of course, the target carbon ratio of the SP³ hybrid bonds 400 to the SP² hybrid bonds 300 in the film layer 3 can also be other values, which are not listed here.

In an exemplary embodiment of the present disclosure, the ratio of SP² hybrid bonds 300 and SP³ hybrid bonds 400 in the target carbon film layer 3 can be detected after the implantation of modifying ions, so as to determine whether the target carbon film layer 3 is formed and whether the hardness of the initial carbon film layer 2 is improved.

For example, the X-ray photoelectron spectrum (XPS) of the initial carbon film layer 2 and the target carbon film layer 3 can be collected respectively, and the SP² impurities in the target carbon film layer 3 can be judged according to the peak value in the XPS whether the ratio of SP² hybrid bond 300 to SP³ hybrid bond 400 is changed compared with the ratio of SP² hybrid bond 300 to SP³ hybrid bond 400 in the initial carbon film layer 2. FIG. 5 shows the X-ray photoelectron spectrum (XPS) of the original carbon film layer 2 in the embodiment of the present disclosure, and FIG. 6 shows the XPS of the target carbon film layer 3 in the embodiment of the present disclosure, in the figure, the X-axis represents the binding energy; the Y-axis represents the photoelectron intensity; 284.7 ev is the characteristic peak of carbon SP² hybridization; the 285 ev binding energy represents the characteristic peak of carbon SP³ hybridization; according to FIG. 5 and FIG. 6, it can be concluded that the peak area of SP³ hybridization in the target carbon film layer 3 becomes larger, indicating that the proportion of SP³ in the carbon film layer formed after the modifying ion implantation becomes larger.

After calculation, it can be known that the ratio of SP³ hybrid bond 400 and SP² hybrid bond 300 in the initial carbon film layer 2 is 29.76:70.24; the ratio of SP³ hybrid bond 400 and SP² hybrid bond 300 in the target carbon film layer 3 is 42.15:57.85, compared with the initial carbon film layer 2, the proportion of SP³ hybrid bond 400 increased by 41.6%.

In order to further verify whether the hardness of the target carbon film layer 3 formed after the modifying ion implantation can be increased, and then determine whether the etching selectivity ratio of the target carbon film layer 3 formed after the modifying ion implantation can be increased, and can be respectively adopted. The target carbon film layer 3 and the initial carbon film layer 2 are used as a mask layer, and the film layer to be tested is etched, and the target carbon film layer 3 is determined by comparing the morphology of the etching window formed in the film layer to be tested after etching whether the etch selectivity ratio can be improved.

For example, as shown in FIG. 7, the film layer 5 to be tested can be formed on a substrate 4, the target carbon film layer 3 is formed on the surface of the film layer 5 to be tested, and at the same time, the film layer to be measured is formed on another substrate 4 5. Form an initial carbon film layer 2 on the surface of the film layer 5 to be tested; adopt the same process to form the same mask pattern in the initial carbon film layer 2 and the target carbon film layer 3 respectively; the carbon film layer 2 and the target carbon film layer 3 are masks, and the same etching gas or etching solution is used to etch the film layer 5 to be tested to form an etching window 501; the initial carbon film layer 2 with the mask pattern and the microscopic appearance of the etching window 501 formed with the target carbon film layer 3 with the mask pattern as a mask, and then judge the etching selection of the target carbon film layer 3 by the microscopic appearance whether the ratio is greater than the time selection ratio of the initial carbon film layer 2.

The side wall profile of the etching window 101 formed by using the initial carbon film layer 2 as a mask appears to have a large upper part and a narrower lower part; the side wall profile of the etching window 501 formed by using the target carbon film layer 3 as a mask is straighter and does not appear. The phenomenon that the large bottom is narrow indicates that the hardness of the target carbon film layer 3 is greater and the etching selectivity is higher.

In an exemplary embodiment of the present disclosure, since the hardness of the target carbon film layer 3 is increased compared with the initial carbon film layer 2, in the process of etching with the target carbon film layer 3 as a mask, the etching rate of the target carbon film layer 3 is lower than that of the initial carbon film layer 2, that is, the etching selectivity of the target carbon film layer 3 is higher than that of the initial carbon film layer 2.

In an exemplary embodiment of the present disclosure, after a large number of experimental verifications, the target carbon film layer obtained under the condition that the thickness of the initial carbon film layer 2 is about 160 nm and the implantation amount of modifying ions is 3.00×10¹⁵ ions/cm² is finally obtained 3 has the lowest etch rate and the highest hardness. The etching rate of the target carbon film layer 3 formed after modifying ion implantation was 32.9, which was 25% lower than that of the initial carbon film layer 2 (with an etching rate of 42.6) without modifying ion implantation.

Other embodiments of the present disclosure will be readily apparent to those skilled in the art from consideration of the specification and practice of the invention disclosed herein. This application is intended to cover any modification, use or adaptation of the present disclosure, and these modifications, uses or adaptations follow the general principles of the present disclosure and include common knowledge or conventional technical means in the technical field not disclosed in the present disclosure. The specification and examples are to be considered exemplary only, with the true scope and spirit of the disclosure indicated by the appended claims.

1. A method for forming a semiconductor structure, comprising:
providing a substrate;
forming an initial carbon film layer on a surface of the substrate, wherein the initial carbon film layer includes SP² hybrid bonds; and
implanting modifying ions into the initial carbon film layer, wherein the modifying ions convert the SP² hybrid bonds into SP³ hybrid bonds to obtain a target carbon film layer.

2. The method according to claim 1, wherein a hardness of the target carbon film layer is greater than a hardness of the initial carbon film layer.

3. The method according to claim 1, wherein an etching selectivity of the target carbon film layer is higher than an etching selectivity of the initial carbon film layer.

4. The method according to claim 1, wherein a step of forming the initial carbon film layer having SP² hybrid bonds comprises:
plasma-bombarding a carbon-containing gas at a first preset temperature, a first preset power, a first preset frequency, and a first preset pressure to form an initial carbon film attached to the surface of the substrate.

5. The method of claim 4, wherein the carbon-containing gas comprises cyclopropane.

6. The method according to claim 4, wherein the first preset temperature has a range of 300° C.˜650° C., the first preset power has a range of 1500 W˜2500 W, and the first preset frequency has a range of 10 MHZ˜15 MHZ, and the first preset pressure has a range of 3 torr˜10 torr.

7. The method according to claim 1, wherein a step of implanting the modifying ions into the initial carbon film layer to convert the SP² hybrid bonds into SP³ hybrid bonds to obtain the target carbon film layer comprises:
ionizing a modifying gas at a second preset temperature to form the modifying ions;
accelerating the modifying ions to form a high-energy ion beam; and
injecting the high-energy ion beam into the initial carbon film layer to form the target carbon film layer after the high-energy ion beam passes through an electric field.

8. The method according to claim 7, wherein the modifying gas is carbon monoxide, and wherein the modifying ions are carbon ions.

9. The method according to claim 7, wherein the modifying gas is diborane, and wherein the modifying ions are boron ions.

10. The method according to claim 7, wherein the second preset temperature is in a range of normal temperature (room temperature).

11. The method according to claim 7, wherein a thickness of the initial carbon film layer comprises a range of 100 nm-300 nm.

12. The method according to claim 7, wherein an implantation depth of the modifying ions of the initial carbon film layer is less than ⅔ of a thickness of the initial carbon film layer.

13. The method according to claim 7, wherein an implantation amount of the modifying ions is in a range of 1×10¹⁵ ions/cm²˜4×10¹⁵ ions/cm².

14. A semiconductor structure, comprising:
a substrate; and
a target carbon film layer, wherein the target carbon film layer comprises SP² hybrid bonds and SP³ hybrid bonds, wherein the target carbon film layer is formed by implanting modifying ions to an initial carbon film layer disposed on the substrate, and wherein a SP² hybrid bond content of the target carbon film layer is higher than a SP² hybrid bond content of the initial carbon film layer.

15. The semiconductor structure of claim 14, wherein a hardness of the target carbon film layer is greater than a hardness of the initial carbon film layer.

16. The semiconductor structure according to claim 14, wherein an etch selectivity of the target carbon film layer is higher than an etch selectivity of the initial carbon film layer.
